(19) United States
(12) Patent Application Publication
(10) Pub. No.: US 2006/0118969 A1
(43) Pub. Date: Jun. 8, 2006

(54) Flip chip ball grid array package assemblies and electronic devices with heat dissipation capability

(75) Inventor: Tsorng-Dih Yuan, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/002,240

(22) Filed: Dec. 3, 2004

(51) Int. Cl. H01L 23/48

(52) U.S. Cl. 257/778

(57) ABSTRACT

Flip chip ball grid array package assemblies. A chip is disposed on a substrate. A plurality of flip chip balls is connected between the chip and the substrate. A heat spreader is disposed on the chip and includes a first surface and a second surface opposite thereto. The first surface is connected to the chip, and the second surface includes at least one protrusion. A heat sink is connected to the heat spreader and includes at least one recess. The profile of the recess is complementary to that of the protrusion of the heat spreader. The protrusion is positioned in the recess. A plurality of ball grid array electrodes is disposed under the substrate.

### BACKGROUND

The invention relates to flip chip ball grid array package assemblies, and in particular to flip chip ball grid array package assemblies providing enhanced thermal conduction.

Referring to FIG. 1, a conventional flip chip plastic ball grid array (FC-PBGA) package 1 comprises a plurality of plastic ball grid array electrodes 11, a substrate 12, a chip or an integrated circuit 13, a plurality of flip chip balls 14, two reinforcing members 15, and a heat spreader 16.

The chip 13 is disposed on the substrate 12 by means of the flip chip balls 14. Glue 17 fills the area between the chip 13, the flip chip balls 14, and the substrate 12, protecting the flip chip balls 14 and fixing the chip 13 and flip chip balls 14 on the substrate 12. A circuit 18 may be formed on the bottom of the chip 13. Electronic signals are transmitted between the chip 13 (circuit 18) and the substrate 12 via the flip chip balls 14 which serve as interconnection portions of the flip chip plastic ball grid array package 1. The heat spreader 16 is disposed on the chip 13. Heat generated from the chip 13 can be transferred (conducted) to the heat spreader 16 and further to the environment. Specifically, a thermal interface material 19 is filled between the heat spreader 16 and the chip 13. The heat generated from the chip 13 is transferred (conducted) to the heat spreader 16 via the thermal interface material 19. The reinforcing members 15 are respectively disposed on two opposite sides of the substrate 12 and between the heat spreader 16 and the substrate 12, enhancing rigidity, or strength, of the flip chip plastic ball grid array package 1.

Moreover, the flip chip plastic ball grid array package 1 can be disposed on a printed circuit board 2 by means of the plastic ball grid array electrodes 11. Thus, electronic signals can be transmitted between the chip 13 (circuit 18), the substrate 12, and the printed circuit board 2 via the flip chip balls 14 and plastic ball grid array electrodes 11.

Moreover, when the chip 13 operates at a higher power, more heat is generated therefrom. When this occurs, an additional heat sink 3 is required on the heat spreader 16 to assist heat dissipation, as shown in FIG. 2. Specifically, another thermal interface material 31, such as epoxy adhesive, is filled between the heat spreader 16 and the heat sink 3. The heat conducted to the heat spreader 16 can be transferred (conducted) to the heat sink 3 via the thermal interface material 31 and further to the environment from the heat sink 3.

Accordingly, since heat in the heat spreader 16 is transferred to the heat sink 3 by thermal conduction, the interface between the heat spreader 16 and the heat sink 3 must be flat. Namely, the top surface of the heat spreader 16 and bottom surface of the heat sink 3 must be flat to obtain a low thermal resistance therebetween. Thus, thermal conduction between the heat spreader 16 and the heat sink 3 does not deteriorate.

The efficiency of thermal conduction between the heat spreader 16 and the heat sink 3 can be approximately analyzed using the following formulas for heat transfer:
ΔT=P×Rᵢₙₜ
Rᵢₙₜ=l/K×A,

Wherein ΔT denotes the temperature increase of the chip 13, P denotes the operating power provided by the chip 13, Rᵢₙₜ denotes the thermal resistance of the thermal interface material 31 (interface), l denotes the thickness of the thermal interface material 31 (interface), K denotes the thermal conduction coefficient of the thermal interface material 31, and A denotes the interface area between the heat spreader 16 and the heat sink 3.

The less the Rᵢₙₜ, the lower the ΔT. Namely, the heat generated from the chip 13 can be easily conducted to the heat sink 3 via the heat spreader 16. Accordingly, to reduce Rᵢₙₜ, l (the thickness of the thermal interface material 31) must be reduced or K (the thermal conduction coefficient of the thermal interface material 31) must be increased when A (the interface area) is fixed.

Nevertheless, when l is reduced, air voids easily exist between the thermal interface material 31 and the heat spreader 16 and between the thermal interface material 31 and the heat sink 3 if the top surface of the heat spreader 16 and bottom surface of the heat sink 3 are uneven. The thermal conduction coefficient of air, however, is very small, thus increasing thermal resistance. To solve the aforementioned issue of increased thermal resistance, both the top surface of the heat spreader 16 and bottom surface of the heat sink 3 must be flat. A flattening process performed on the heat spreader 16 and heat sink 3, however, may result in increased manufacturing cost.

Alternatively, a material with a larger thermal conduction coefficient can serve as the thermal interface material 31 to reduce Rᵢₙₜ. The material with a larger thermal conduction coefficient, however, is usually expensive, also resulting in increased manufacturing cost.

Moreover, intermittent operation of the chip 13 causes frequent thermal expansion and contraction of the heat spreader 16 and heat sink 3. The interface between the heat spreader 16 and the heat sink 3 is easily damaged (thermal interface material 31 separates from the heat spreader 16 or heat sink 3) due to frequent thermal expansion and contraction, thereby reducing the thermal conduction therebetween.

Hence, a flip chip ball grid array package assembly with an increased interface area between a heat spreader and a heat sink thereof is desirable. The thermal conduction between the heat spreader and the heat sink is enhanced by the increased interface area.

### SUMMARY

Flip chip ball grid array package assemblies are provided. An exemplary embodiment of a flip chip ball grid array package assembly comprises a substrate, a chip, a plurality of flip chip balls, a heat spreader, a heat sink, and a plurality of ball grid array electrodes. The chip is disposed on the substrate. The flip chip balls are connected between the chip and the substrate. The heat spreader is disposed on the chip and comprises a first surface and a second surface opposite thereto. The first surface is connected to the chip. The second surface comprises at least one protrusion. The heat sink is connected to the heat spreader and comprises at least one recess. The profile of the recess is complementary to that of the protrusion of the heat spreader. The protrusion is positioned in the recess. The ball grid array electrodes are disposed under the substrate.

Some embodiments of a flip chip ball grid array package assembly comprise at least one reinforcing member disposed between the substrate and the heat spreader to enhance rigidity thereof.

Some embodiments of a heat sink comprise a plurality of fins opposite to the recess.

Some embodiments of a chip comprise an integrated circuit or a microprocessor.

Some embodiments of a flip chip ball grid array package assembly comprise a thermal interface layer formed between the heat spreader and the heat sink.

An exemplary embodiment of an electronic device with heat dissipation capability comprises an electronic component, a heat spreader, and a heat sink. The heat spreader is disposed on the electronic component and comprises a first surface and a second surface opposite thereto. The first surface is, connected to the electronic component. The second surface comprises at least one protrusion. The heat sink is connected to the heat spreader and comprises at least one recess. The profile of the recess is complementary to that of the protrusion of the heat spreader. The protrusion is positioned in the recess. Heat generated from the electronic component is transferred to the environment via the heat spreader and heat sink.

Some embodiments of an electronic device comprise a substrate disposed under the electronic component to support the electronic component.

Some embodiments of an electronic device comprise at least one reinforcing member disposed between the substrate and the heat spreader to enhance rigidity of the electronic device.

Some embodiments of a heat sink comprise a plurality of fins opposite to the recess.

Some embodiments of an electronic component comprise an integrated circuit or a microprocessor.

Some embodiments of an electronic device comprise a thermal interface layer formed between the heat spreader and the heat sink.

### DESCRIPTION OF THE DRAWINGS

The invention can be more fully understood by reading the subsequent detailed description and examples with references made to the accompanying drawings, wherein:

FIG. 1 is a schematic side view of a conventional flip chip plastic ball grid array package;

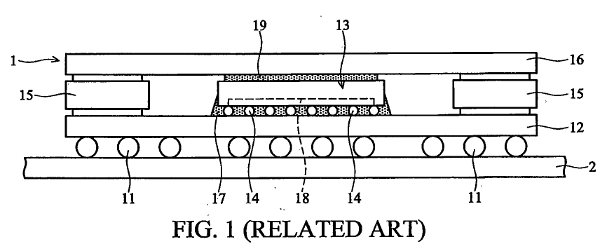

FIG. 2 is a schematic side view of a conventional flip chip plastic ball grid array package combined with a heat sink;

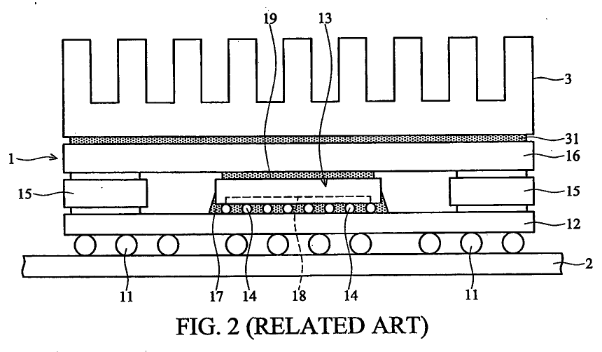

FIG. 3 is a schematic side view of an embodiment of a flip chip ball grid array package assembly; and

FIG. 4 is a schematic side view of an embodiment of a flip chip ball grid array package assembly.

### DETAILED DESCRIPTION

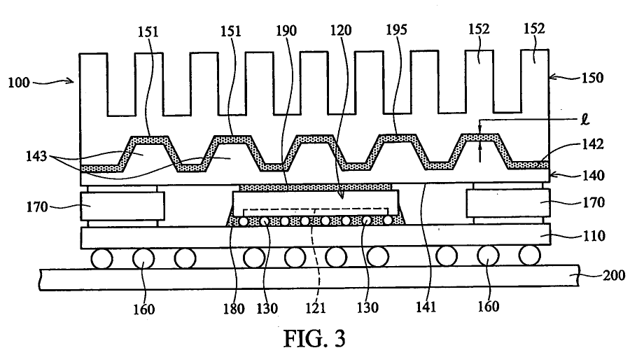

Referring to FIG. 3, a flip chip ball grid array (FC-BGA) package assembly 100 comprises a substrate 110, a chip (an electronic component) 120, a plurality of flip chip balls 130, a heat spreader 140, a heat sink 150, a plurality of ball grid array electrodes 160, and two reinforcing members 170.

The chip (electronic component) 120 is disposed on the substrate 110 by means of the flip chip balls 130. Glue 180 fills the area between the chip 120, the flip chip balls 130, and the substrate 110, protecting the flip chip balls 130 and fixing the chip 120 and flip chip balls 130 on the substrate 110. Additionally, a circuit 121 may be formed on the bottom of the chip 120. Electronic signals are transmitted between the chip 120 (circuit 121) and the substrate 110 via the flip chip balls 130 which serve as interconnection portions of the flip chip ball grid array package assembly 100. The chip (electronic component) 120 may be an integrated circuit or a microprocessor.

The heat spreader 140 is disposed on the chip 120 and comprises a first surface 141 and a second surface 142 opposite thereto. The first surface 141 may be connected to the chip 120 by means of a thermal interface material 190. Heat generated from the chip 120 can be transferred (conducted) to the heat spreader 140 via the thermal interface material 190. Specifically, the second surface 142 of the heat spreader 140 is formed with a plurality of protrusions 143.

The heat sink 150 is connected to the heat spreader 140 and comprises a plurality of recesses 151. Specifically, the profile of each recess 151 is complementary to that of each protrusion 143 of the heat spreader 140. When the heat sink 150 is connected to the heat spreader 140, each protrusion 143 is positioned in each recess 151. Additionally, a thermal interface layer 195 is formed between the heat spreader 140 and the heat sink 150. The thermal interface layer 195 may comprise epoxy adhesives. The heat conducted to the heat spreader 140 is transferred (conducted) to the heat sink 150 via the thermal interface layer 195. The heat is then transferred to the environment from the heat sink 150. Furthermore, the heat sink 150 comprises a plurality of fins 152 opposite to the recesses 151 to assist heat dissipation.

The reinforcing members 170 are respectively disposed on two opposite sides of the substrate 110 and between the heat spreader 140 and the substrate 110, enhancing rigidity or strength of the flip chip ball grid array package assembly 100.

The ball grid array electrodes 160 are disposed under the substrate 110. The flip chip ball grid array package assembly 100 can be electrically connected to a printed circuit board 200 by means of the ball grid array electrodes 160.

Accordingly, the heat in the heat spreader 140 is transferred to the heat sink 150 by thermal conduction. The efficiency of thermal conduction between the heat spreader 140 and the heat sink 150 can be approximately analyzed according to ΔT=P×Rᵢₙₜ and Rᵢₙₜ=l/K×A.

Since the heat spreader 140 is connected to the heat sink 150 by the protrusions 143 engaging the recesses 151, the interface area (A) between the heat spreader 140 and the heat sink 150 is far greater than that between the heat spreader 16 and the heat sink 3 of the conventional flip chip ball grid array package 1. When the thickness of the thermal interface layer 195 (or interface) and material thereof are fixed, the thermal resistance (Rᵢₙₜ) between the heat spreader 140 and the heat sink 150 is substantially reduced. Accordingly, the thermal conduction between the heat spreader 140 and the heat sink 150 is greatly enhanced and less heat accumulates on the chip 120.

Although the top surface (second surface 142) of the heat spreader 140 and bottom surface of the heat sink 150 are uneven allowing air voids to occur between the thermal interface material 195 and the heat spreader 140 and between the thermal interface material 195 and the heat sink 150, the thermal conduction between the heat spreader 140 and the heat sink 150 is not reduced as compared to that between the heat spreader 16 and the heat sink 3 of the conventional flip chip plastic ball grid array package 1. Specifically, although the air voids result in a reduced thermal conduction coefficient (K) in the interface (thermal interface material 195), the interface area enormously increased between the heat spreader 140 and the heat sink 150 can compensate for the reduced thermal conduction coefficient. Accordingly, a high level is not required on the top surface (second surface 142) of the heat spreader 140 and bottom surface of the heat sink 150, thus reducing manufacturing cost of the flip chip ball grid array package assembly 100.

Accordingly, since the interface area (A) between the heat spreader 140 and the heat sink 150 is enormously increased, the thermal conduction coefficient (K) of the thermal interface material 195 is not necessarily high. Thus, use of the thermal interface material 195 with a low thermal conduction coefficient (K) can also reduce the manufacturing costs of the flip chip ball grid array package assembly 100.

Additionally, since the heat spreader 140 is connected to the heat sink 150 by the protrusions 143 engaging the recesses 151, rigidity or strength of the connection therebetween is enhanced.

Similarly, since the heat spreader 140 is connected to the heat sink 150 by the protrusions 143 engaging the recesses 151, the connection therebetween is more flexible. Specifically, even though the chip 120 operates intermittently, the heat spreader 140 and heat sink 150 are not easily bent or deformed by thermal expansion and contraction. The interface between the heat spreader 140 and the heat sink 150 is thus not damaged (the thermal interface material 195 is not separated from the heat spreader 140 or heat sink 150).

Moreover, the protrusions 143 of the heat spreader 140 and recesses 151 of the heat sink 150 may be interchangeable. Namely, a plurality of protrusions may be formed on the heat sink 150 while a plurality of recesses may be formed on the heat spreader 140, achieving the same thermal conduction results.

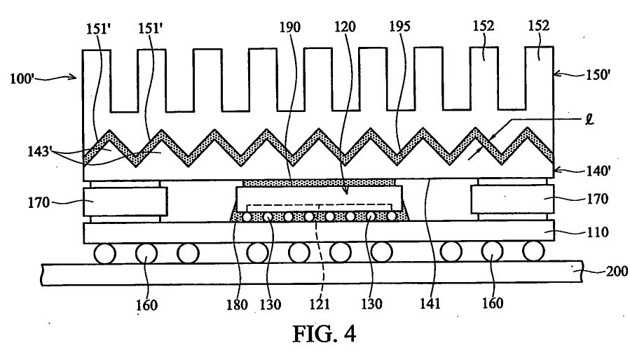

Alternatively, as shown in FIG. 4, a flip chip ball grid array package assembly 100′ comprises a heat spreader 140′ and a heat sink 150′. The heat spreader 140′ comprises a plurality of saw-toothed protrusions 143′ and the heat sink 150′ comprises a plurality of saw-toothed recesses 151′. Similarly, the profile of each saw-toothed recess 151′ is complementary to that of each saw-toothed protrusion 143′. When the heat sink 150′ is connected to the heat spreader 140′, each saw-toothed protrusion 143′ is positioned in each saw-toothed recess 151′. Thus, the interface area (A) between the heat spreader 140′ and the heat sink 150′ is enormously increased as compared to that between the heat spreader 16 and the heat sink 3 of the conventional flip chip plastic ball grid array package 1, as well enhancing the thermal conduction between the heat spreader 140′ and the heat sink 150′.

Structure, disposition, and function of other elements of the flip chip ball grid array package assembly 100′ are the same as those of the flip chip ball grid array package assembly 100, and explanation thereof is omitted for simplicity.

In conclusion, the profiles of the heat spreader and heat sink are not limited to those presented in the flip chip ball grid array package assemblies 100 and 100′. For example, the profile of the interface between the heat spreader and the heat sink can be designed using finite element simulation to further enlarge the interface area therebetween, thereby further enhancing the thermal conduction therebetween.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flip chip ball grid array package assembly, comprising:
a substrate;
a chip disposed on the substrate;
a plurality of flip chip balls connected between the chip and the substrate;
a heat spreader disposed on the chip and comprising a first surface and a second surface opposite thereto, wherein the first surface is connected to the chip, and the second surface comprises at least one protrusion;
a heat sink connected to the heat spreader and comprising at least one recess, wherein the profile of the recess is complementary to that of the protrusion of the heat spreader, and the protrusion is positioned in the recess; and
a plurality of ball grid array electrodes disposed under the substrate.

2. The flip chip ball grid array package assembly as claimed in claim 1, further comprising at least one reinforcing member disposed between the substrate and the heat spreader to enhance rigidity of the flip chip ball grid array package assembly.

3. The flip chip ball grid array package assembly as claimed in claim 1, wherein the heat sink further comprises a plurality of fins opposite to the recess.

4. The flip chip ball grid array package assembly as claimed in claim 1, wherein the chip comprises an integrated circuit.

5. The flip chip ball grid array package assembly as claimed in claim 1, wherein the chip comprises a microprocessor.

6. The flip chip ball grid array package assembly as claimed in claim 1, further comprising a thermal interface layer formed between the heat spreader and the heat sink.

7. A flip chip ball grid array package assembly, comprising:
a substrate;
a chip disposed on the substrate;
a plurality of flip chip balls connected between the chip and the substrate;
a heat spreader disposed on the chip and comprising a first surface and a second surface opposite thereto, wherein the first surface is connected to the chip, and the second surface comprises at least one recess;
a heat sink connected to the heat spreader and comprising at least one protrusion, wherein the profile of the protrusion is complementary to that of the recess of the heat spreader, and the protrusion is positioned in the recess; and
a plurality of ball grid array electrodes disposed under the substrate.

8. The flip chip ball grid array package assembly as claimed in claim 7, further comprising at least one reinforcing member disposed between the substrate and the heat spreader to enhance rigidity of the flip chip ball grid array package assembly.

9. The flip chip ball grid array package assembly as claimed in claim 7, wherein the heat sink further comprises a plurality of fins opposite to the protrusion.

10. The flip chip ball grid array package assembly as claimed in claim 7, wherein the chip comprises an integrated circuit.

11. The flip chip ball grid array package assembly as claimed in claim 7, wherein the chip comprises a microprocessor.

12. The flip chip ball grid array package assembly as claimed in claim 7, further comprising a thermal interface layer formed between the heat spreader and the heat sink.

13. An electronic device with capability of heat dissipation, comprising:
an electronic component;
a heat spreader disposed on the electronic component and comprising a first surface and a second surface opposite thereto, wherein the first surface is connected to the electronic component, and the second surface comprises at least one protrusion; and
a heat sink connected to the heat spreader and comprising at least one recess, wherein the profile of the recess is complementary to that of the protrusion of the heat spreader, the protrusion is positioned in the recess, and heat generated from the electronic component is transferred to the environment via the heat spreader and heat sink.

14. The electronic device as claimed in claim 13, further comprising a substrate disposed under the electronic component to support the electronic component.

15. The electronic device as claimed in claim 14, further comprising at least one reinforcing member disposed between the substrate and the heat spreader to enhance rigidity of the electronic device.

16. The electronic device as claimed in claim 13, wherein the heat sink further comprises a plurality of fins opposite to the recess.

17. The electronic device as claimed in claim 13, wherein the electronic component comprises an integrated circuit.

18. The electronic device as claimed in claim 13, wherein the electronic component comprises a microprocessor.

19. The electronic device as claimed in claim 13, further comprising a thermal interface layer formed between the heat spreader and the heat sink.

20. An electronic device with capability of heat dissipation, comprising:
an electronic component;
a heat spreader disposed on the electronic component and comprising a first surface and a second surface opposite thereto, wherein the first surface is connected to the electronic component, and the second surface comprises at least one recess; and
a heat sink connected to the heat spreader and comprising at least one protrusion, wherein the profile of the protrusion is complementary to that of the recess of the heat spreader, the protrusion is positioned in the recess, and heat generated from the electronic component is transferred to the environment via the heat spreader and heat sink.

21. The electronic device as claimed in claim 20, further comprising a substrate disposed under the electronic component to support the electronic component.

22. The electronic device as claimed in claim 21, further comprising at least one reinforcing member disposed between the substrate and the heat spreader to enhance rigidity of the electronic device.

23. The electronic device as claimed in claim 20, wherein the heat sink further comprises a plurality of fins opposite to the recess.

24. The electronic device as claimed in claim 20, wherein the electronic component comprises an integrated circuit.

25. The electronic device as claimed in claim 20, wherein the electronic component comprises a microprocessor.

26. The electronic device as claimed in claim 20, further comprising a thermal interface layer formed between the heat spreader and the heat sink.
